(19) United States
(12) Patent Application Publication
(10) Pub. No.: US 2017/0208281 A1
(43) Pub. Date: Jul. 20, 2017

(54) PIXEL, IMAGE SENSING DEVICE INCLUDING THE PIXEL AND METHOD FOR DRIVING THE IMAGE SENSING DEVICE

(71) Applicant: SK hynix Inc., Gyeonggi-do (KR)

(72) Inventors: Pyong-Su KWAG, Gyeonggi-do (KR); Sung-Kun PARK, Gyeonggi-do (KR); Dong-Hyun WOO, Gyeonggi-do (KR)

(21) Appl. No.: 15/154,799

(22) Filed: May 13, 2016

(30) Foreign Application Priority Data
Jan. 19, 2016 (KR) 10-2016-0006417

(51) Int. Cl. H04N 5/3745; H01L 27/146

(52) U.S. Cl. CPC H04N 5/3745; H01L 27/14643; H01L 27/14609

(57) ABSTRACT

A pixel includes: a charge transmission node; an initialization block suitable for initializing the charge transmission node with a first voltage during a data initialization period; a photodiode suitable for generating a photocharge based on incident light during an exposure period; a transmission block suitable for transmitting the photocharge to the charge transmission node during a transmission period; a first accumulation block suitable for boosting the charge transmission node with a second voltage during a boosting period and accumulating the photocharge transmitted to the charge transmission node during the transmission period; and a selection block suitable for generating a pixel signal corresponding to a voltage loaded on the charge transmission node during a selection period.

### CROSS-REFERENCE TO RELATED APPLICATIONS

The present application claims priority of Korean Patent Application No. 10-2016-0006417, filed on Jan. 19, 2016, which is incorporated herein by reference in its entirety.

### BACKGROUND

1. Field

Exemplary embodiments of the present invention relate generally to a semiconductor design technology and, more particularly, to a pixel, an image sensing device including the pixel and a method for driving the image sensing device.

2. Description of the Related Art

Image sensing devices capture images using photosensitive properties of semiconductors. Image sensing devices are often classified into charge-coupled device (CCD) image sensors and complementary metal-oxide semiconductor (CMOS) image sensors. CMOS image sensors allow for both analog and digital control circuits to be directly realized on a single integrated circuit (IC), making CMOS image sensors the most widely used type of image sensor.

### SUMMARY

Exemplary embodiments of the present invention are directed to a pixel having an improved transmission capability for transmitting a photocharge generated from a photodiode to a charge transmission node, an image sensing device including the pixel, and a method for driving the image sensing device.

In accordance with an embodiment of the present invention, a pixel includes: a charge transmission node; an initialization block suitable for initializing the charge transmission node with a first voltage during a data initialization period; a photodiode suitable for generating a photocharge based on incident light during an exposure period; a transmission block suitable for transmitting the photocharge to the charge transmission node during a transmission period; a first accumulation block suitable for boosting the charge transmission node with a second voltage during a boosting period and accumulating the photocharge transmitted to the charge transmission node during the transmission period; and a selection block suitable for generating a pixel signal corresponding to a voltage loaded on the charge transmission node during a selection period.

The first accumulation block may include a parallel-plate capacitor.

The first voltage and the second voltage may have the same voltage level or different voltage levels.

The selection block may include: a driving unit suitable for driving the pixel signal with the first voltage; and an output unit suitable for outputting the pixel signal during the selection period.

The selection block may include: a driving unit suitable for driving the pixel signal with the second voltage; and an output unit suitable for outputting the pixel signal during the selection period.

The pixel may further include: a second accumulation block formed between the charge transmission node and a ground voltage terminal and suitable for accumulating the photocharge transmitted to the charge transmission node during the transmission period.

The second accumulation block may include a junction capacitor.

The initialization block may initialize the first accumulation block with the first voltage during a pixel initialization period, and the transmission block may initialize the photodiode with the first voltage during the pixel initialization period.

In accordance with another embodiment of the present invention, an image sensing device includes: a control block suitable for generating an initialization control signal, a transmission control signal and a selection control signal that pulse within a first voltage range and generating a boost control signal that pulses within a second voltage range; and a pixel suitable for initializing a charge transmission node before a transmission period, boosting the charge transmission node based on a capacitive coupling effect during the transmission period, transmitting a photocharge generated from a photodiode to the charge transmission node during the transmission period, and generating a pixel signal corresponding to a voltage loaded on the charge transmission node during the transmission period, based on the initialization control signal, the transmission control signal, the selection control signal'and the boost control signal,

The pixel may include: a charge transmission node; an initialization block suitable for initializing the charge transmission node with a first voltage based on the initialization control signal; the photodiode suitable for generating the photocharge based on incident light during an exposure period; a transmission block suitable for transmitting the photocharge to the charge transmission node based on the transmission control signal; a first accumulation block suitable for boosting the charge transmission node with a second voltage corresponding to the boost control signal and accumulating the photocharge transmitted to the charge transmission node; and a selection block suitable for generating the pixel signal corresponding to the voltage loaded on the charge transmission node based on the selection con trot' signal.

The first accumulation block may include a parallel-plate capacitor.

The first voltage and the second voltage may have the same voltage level or different voltage levels.

The selection block may include: a driving unit suitable for driving the pixel signal with the first voltage; and an output unit suitable for outputting the pixel signal.

The selection block may include: a driving unit suitable for driving the pixel signal with the second voltage; and an output unit suitable for outputting the pixel signal.

The pixel may further include: a second accumulation block formed between the charge transmission node and a ground voltage terminal and suitable for accumulating the photocharge transmitted to the charge transmission node during the transmission period.

The second accumulation block may include a junction capacitor.

The initialization block may initialize the first accumulation block with the first voltage during a pixel initialization period before the exposure period based on the initialization control signal, and the transmission block may initialize the photodiode with the first voltage during the pixel initialization period based on the transmission control signal.

In accordance with another embodiment of the present invention, a method for driving an image sensing device includes: initializing a charge transmission node with a first voltage; and transmitting a photocharge generated from a photodiode to the charge transmission node and generating a pixel signal based on a voltage loaded on the charge transmission node when the charge transmission node is boosted with a second voltage based on a capacitive coupling effect.

The initializing of the charge transmission node with the first voltage may be carried out during a data initialization period before a selection period, and the generating of the pixel signal may include boosting the charge transmission node during the selection period, generating a reference signal corresponding to the first and second voltages as the pixel signal during a reference period of the selection period, and transmitting the photocharge to the charge transmission node and generating a data signal corresponding to the photocharge as the pixel signal during a transmission period of the selection period.

The method may further include: initializing the transmission node and the photodiode with the first voltage before the initializing of the charge transmission node with the first voltage.

### BRIEF DESCRIPTION OF THE DRAWINGS

FIG. 1 is a block diagram illustrating an image sensing device, according to an embodiment of the present invention.

FIG. 2 is a circuit diagram illustrating a pixel, according to an embodiment of the present invention.

FIG. 3 is a timing diagram for describing an operation of an image sensing device, according to an embodiment of the present invention.

FIG. 4 is a block diagram illustrating an image sensing device, according to another embodiment of the present invention,

FIG. 5 is a circuit diagram illustrating a pixel, according to another embodiment of the present invention.

FIG. 6 is a timing diagram for describing an operation of an image sensing device according to another embodiment of the present invention.

### DETAILED DESCRIPTION

Various embodiments of the present invention will be described below in more detail with reference to the accompanying drawings. These embodiments are provided so that this disclosure is thorough and complete. All “embodiments” referred to in this disclosure refer to embodiments of the inventive concept disclosed herein. The embodiments presented are merely examples and are not intended to limit the invention.

The terminology used herein is for the purpose of describing particular embodiments only and is not intended to be limiting of the inventive concept. As used herein, singular forms are intended to include the plural forms as well, unless the context clearly indicates otherwise. It will be further understood that the terms “comprises,” “comprising,” “includes,” and/or “including” when used in this specification, indicate the presence of stated features, but do not preclude the presence or addition of one or more other features. As used herein, the term “and/or” indicates any and all combinations of one or more of the associated listed items.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order'to clearly illustrate features of the embodiments.

The terminology used herein is for the purpose of describing particular embodiments only and is not intended to be limiting of the present invention. As used herein, singular forms are intended to include the plural forms as well, unless the context clearly indicates otherwise. Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described in detail with reference to the attached drawings.

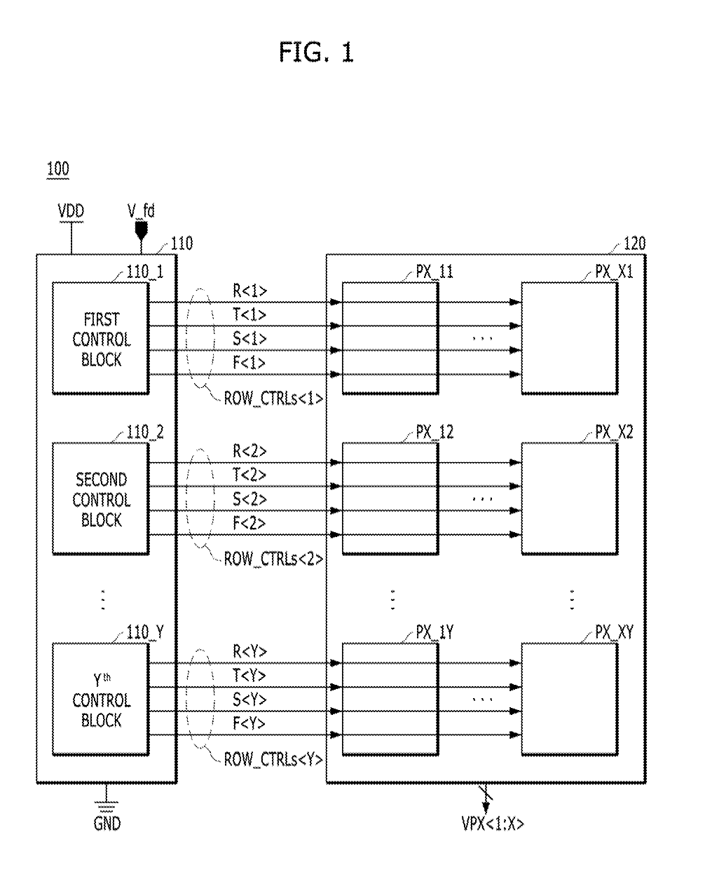

Referring now to FIG. 1, an Image sensing device 100, according to an embodiment: of the present invention, may include a row controller 110 and a pixel array 120,

The row controller 110 may generate first to Y^{th} row control signals ROW_CTRLs<1:Y> for controlling an operation of the pixel array 120 in a row unit, wherein Y is a natural number. For example, the row controller 110 may include first to Y^{th} control blocks 110_1 to 110_Y for generating the first to Y^{th} row control signals ROW_CTRLs<1:Y>. Each of the first to Y row control signals ROW_{—CTRLs<}1:Y>may include an initialization control signal R<#>, a transmission control signal T<#>a selection control signal S<#>, and a boost control signal F<#>, For example, the first row control signal ROW_CTRL<1> may include a first initialization control signal R<1>, a first transmission control signal T<1>, a first selection control signal S<1>, and a first boost control signal F<1>. The Y^{th} row control signal ROW_CTRL<Y> may include a Y^{th} initialization control signal R<Y>, a Y^{th} transmission control signal T<Y>, a Y^{th} selection control signal S<Y>, and a Y^{th} boost control signal F<Y>.

The first to Y^{th} control blocks 110₁₃ 1 to 110_Y , may generate to the first to Y^{th} initialization control signals R<1:Y>, the first to Y^{th} transmission control signals T<1:Y>, and the first to Y^{th} selection control signals S<1:Y>, which may pulse within a first voltage range and may generate the first to Y^{th} boost control signals F<1:Y> which may pulse within a second voltage range. The first voltage range may include a range between a ground voltage GND and a power source voltage VDD. The second voltage range may include a range between the ground voltage GND and a boosted voltage V_fd. The boosted voltage V_fd may have the same voltage level as the power source voltage VDD. The boosted voltage V_fd may have a different voltage level from the power source voltage VDD. For example, the boosted voltage V_fd may have a voltage level lower than the power source voltage VDD.

The pixel array 120 may include a plurality of pixels PX_11 to PX_XY arranged in rows and columns. The pixels PX_11 to PX_XY may generate first to X^{th} pixel signals VPX<1:X>in a row unit based for each of the first to Y^{th} row control signals ROW_CTRLs<1:Y>, wherein X is the number of pixels in a row. For example, the pixels PX_11 to PX_X1 arranged in a first row may simultaneously generate the first to X^{th} pixel signals VPX<1:X> during a first row time based on the first row control signal ROW_CTRL<1>. The pixels PX_1Y to PX_XY arranged in the last row may simultaneously generate the first to X^{th} pixel signals VPX<1:X> during a Y^{th} row time based on the Y^{th} row control signal ROW_CTRL<Y>.

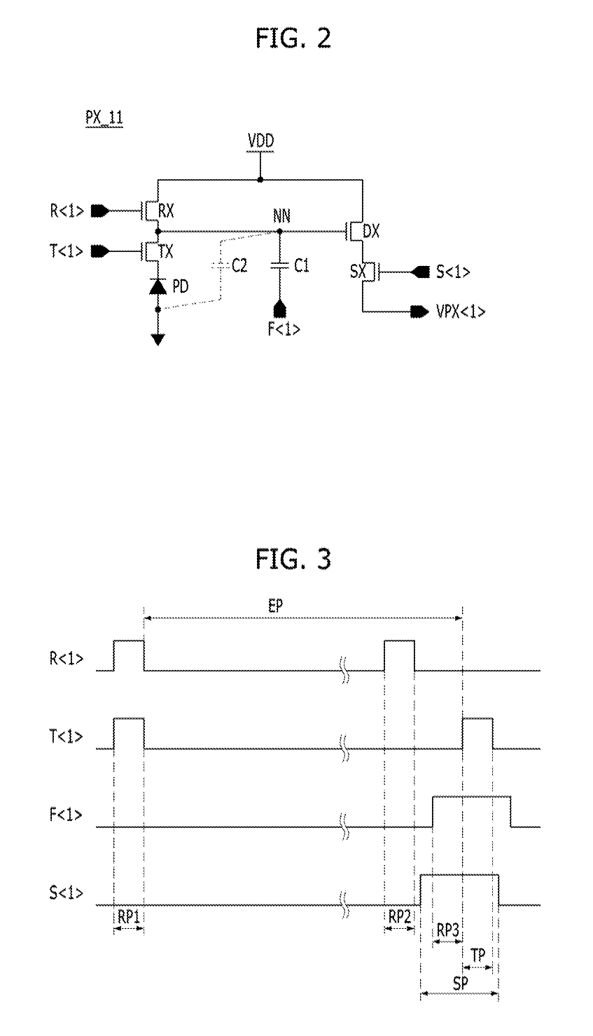

FIG. 2 is a circuit diagram illustrating one of the pixels PX_11 to PX_XY according to an embodiment of the present invention. Since the pixels PX_11 to PX_XY have the same structure, a pixel PX_11 arranged at a cross point of the first row and a first column is representatively described hereafter.

According to the embodiment of FIG. 2, the pixel PX_11 may include a photodiode PD, a charge transmission node NN, an initialization block RX a transmission block TX, a first accumulation block C1 and selection blocks DX and SX.

The photodiode PD may generate a photocharge based on incident light during an exposure period EP. The exposure period EP may include a period ranging from a moment when a pixel initialization period RP1 terminates to a moment when a transmission period TP starts.

The initialization block RX may initialize the charge transmission node NN with the power source voltage VDD based on the first initialization control signal R<1>. To be specific, the initialization block RX may drive the charge transmission node NN with the power source voltage VDD during the pixel initialization period RP1 and a data initialization period RP2. Thus, the initialization block RX may precharge the charge transmission node NN at a voltage level corresponding to the power source voltage VDD at the same time of discharging a charge remaining in the first accumulation block Cl to a power source voltage VDD terminal. The to data initialization period RP2 may include a portion of a period between the pixel initialization period RP1 and a selection period SP. For example, the initialization block RX may include an NMOS transistor having a gate where the first initialization control signal R<1> is inputted and a drain and a source coupled between the power source voltage VDD terminal and the charge transmission node

The transmission block TX may transmit the photocharge to the charge transmission node NN based on the first transmission control signal T<1>. The transmission block TX may transmit the photocharge to the charge transmission node NN during the transmission period TP. The transmission period TP may include a latter period of the selection period SP. The transmission block TX may initialize the photodiode PD based on the first transmission control signal T<1>. The transmission block TX may be enabled along with the initialization block RX during the pixel initialization period RP1 to discharge the photocharge remaining in the photodiode PD to the power source voltage VDD terminal. For example, the transmission block TX may include an NMOS transistor having a gate where the first transmission control signal T<1> is inputted and a drain and a source coupled between the charge transmission node NN and the photodiode PD.

The first accumulation block C1 may boost the charge transmission node NN with the boosted voltage V_fd during a boosting period based on the first boost control signal F<1>. For example, the first accumulation block C1 may include a parallel-plate capacitor and may boost the charge transmission node NN with the boosted voltage V_fd corresponding to the first boost control signal F<1> based on a capacitive coupling effect. The boosting period may include a reference period RP3 and the transmission period TP. The reference period RP3 may include an initial period of the selection period SP. The first accumulation block C1 may accumulate the photocharge transmitted to the charge transmission node NN during the transmission period TP.

The selection blocks DX and SX may generate the first pixel signal VPX<1> corresponding to a voltage loaded on the charge transmission node NN based on the first selection control signal S<1>. The selection blocks DX and SX may generate a reference signal corresponding to the power source voltage VDD and the boosted voltage V_fd as the first pixel signal VPX<1> during the reference period RP3 and generate a data signal corresponding to the photocharge as the first pixel signal VPX<1> during the transmission period TP. For example, the selection blocks DX and SX may include a driving unit DX and an output unit SX. The driving unit DX may drive the first pixel signal VPX<1> with the power source voltage VDD based on the voltage loaded on the charge transmission node NN. For example, the driving unit DX may include an NMOS transistor having a gate coupled to the charge transmission node NN and a drain and a source coupled between the power source voltage VDD terminal and the output unit SX. The output unit SX may output the first pixel signal VPX<1> based on the first selection control signal S<1>. For example, the output unit SX may include an NMOS transistor having a gate where the first selection control signal S<1> is inputted and a drain and a source coupled between the driving unit DX and an output terminal of the first pixel signal VPX<1>.

The pixel PX_11 may further include a second accumulation block C2. The second accumulation block C2 may be formed between the charge transmission node NN and a ground voltage GND terminal. The second accumulation block C2 may accumulate the photocharge transmitted to the charge transmission node NN during the transmission period TP together with the first accumulation block C1. For example, the second accumulation block C2 may include a junction capacitor.

The pixel PX_11 having the aforementioned structure may sequentially generate the reference signal and the data signal as the first pixel signal VPX<1> when the charge transmission node NN is precharged with the power source voltage VDD and boosted with the boosted voltage V_fd, based on the first row control signal ROW_CTRL<1>.

Hereinafter, an operation of the image sensing device 100 having the aforementioned structure is described. As an example, an operation corresponding to the pixel PX_11 arranged at a cross point of the first row and the first column is described below.

FIG. 3 is a timing diagram for describing an operation of the pixel PX_11 included in the image sensing device 100, according to an embodiment of the present invention.

Referring to FIG. 3, the row controller 110 may generate the first row control signal ROW_CTRL<1> during the first row time. For example, the first control block 110_1 may enable the first initialization control signal R<1> and the first transmission control signal T<1> during the pixel initialization period RP1. The first control block 110_1 may also enable the first initialization control signal R<1> during the data initialization period RP2 after the pixel initialization period RP1 and enable the first selection control signal S<1> during the selection period SP. In addition, the first control block 110_1 may enable the first boost control signal F<1> during the reference period RP3 and the transmission period TP and enable the first transmission control signal T<1> during the transmission period TP. The reference period RP3 may include the initial period of the selection period SP. The transmission period TP may include the latter period of the selection period SP.

The pixel PX_11 may generate the first pixel signal VPX<1> based on the first row control signal ROW_CTRL<1>, as described in more detail below.

The pixel PX_11 may initialize the photodiode PD and the charge transmission node NN with the power source voltage VDD during the pixel initialization period RP1 based on the first initialization control signal R<1> and the first transmission control signal T<1>. For example, the initialization block RX may discharge the charge remaining in the first accumulation block C1 to the power source voltage VDD terminal during the pixel initialization period RP1 based on the first initialization control signal R<1>. At the same time, the transmission block TX may discharge the charge remaining in the photodiode PD to the power source voltage VDD terminal through the initialization block RX during the pixel initialization period RP1 based on the first transmission control signal T<1>.

The pixel PX_11 may initialize the charge transmission node NN with the power source voltage VDD during the pixel initialization period RP1 based on the first initialization control signal R<1>. For example, the initialization block RX may precharge the charge transmission node NN with the power source voltage VDD during the data initialization period RP2 based on the first initialization control signal R<1>.

The pixel PK_11 may generate the reference signal corresponding to the power source voltage VDD and the boosted voltage V_d as the first: pixel signal VPX<1> during the reference period RP3 and subsequently generate the data signal corresponding to the photocharge as the first pixel signal VPX<1> during the transmission period TP, based on the first selection control signal S<1>, the first boost control signal F<1> and the first transmission to control signal T<1>. For example, the first accumulation block C1 may boost the charge transmission node NN with the boosted voltage V_fd during the reference period RP3 and the transmission period TP based on the first boost control signal F<1>. For example, the first accumulation block C1 may boost the charge transmission node NN with the boosted voltage V_fd corresponding to the first boost control signal F<1> based on the capacitive coupling effect. The charge transmission node NN may have a combined voltage level VDD+V_fd of the power source voltage VDD and the boosted voltage V_fd. The transmission block TX may transmit the photocharge generated from the photodiode PD to the charge transmission node NN during the transmission period TP based on the first transmission control signal T<1>. The selection blocks DX and SX may generate the reference signal corresponding to the power source voltage VDD and the boosted voltage V_fd as the first pixel signal VPX<1> and generate the data signal corresponding to the photocharge as the first pixel signal VPX<1> during the transmission period TP, based on the voltage loaded on the charge transmission node NN. The selection blocks DX and SX may generate the first pixel signal VPX<1> based on the power source voltage VDD.

The photodiode PD may generate the photocharge during the exposure period EP between a moment when the pixel initialization period RP1 terminates and a moment when the transmission period TP starts.

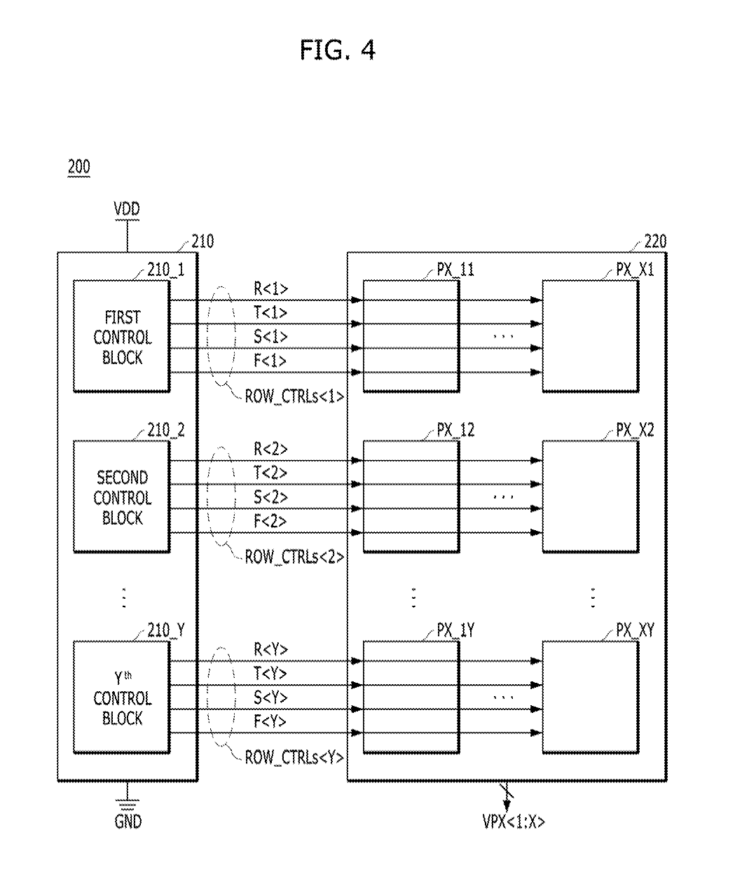

Referring to FIG. 4, an image sensing device 200 according to another embodiment of the present invention may include a row controller 210 and a pixel array 220.

The row controller 210 may generate first to Y^{th} row control signals ROW_CTRLs<1:Y> for controlling an operation of the pixel array 220 in a row unit. For example, the row controller 210 may include first to Y^{th} control blocks 210_1 to 210_Y for generating the first to Y^{th} row control signals ROW_CTRLs<1:Y>. Each of the first to Y^{th} row control signals ROW_CTRLs<1:Y> may include an initialization control signal R<#>, a transmission control signal T<#>, a selection control signal S<#>, and a boost control signal F<#>. For example, the first row control signal ROW_CTRL<1> may include a first initialization control signal R<1>, a first transmission control signal T<1>, a first selection control signal S<1>, and a first boost control signal F<1>, and the Y^{th} row control signal ROW_CTRL<Y> may include a Y^{th} initialization control signal R<Y>, a Y^{th} transmission control signal T<Y>, a Y^{th} selection control signal S<Y> and a Y^{th} boost control signal F<Y>.

The first to Y^{th} control blocks 210_1 to 210_Y may generate the first to Y^{th} initialization control signals R<1:Y> the first to Y^{th} transmission control signals T<1:Y>, the first to Y^{th} selection control signals S<1:Y>and the first to Y^{th} boost control signals F<1:Y> which may pulse within a first voltage range. The first voltage range may include a range between a ground voltage GND and a power to source voltage VDD. Although it is described in the embodiment of the present invention that the first to Y^{th} boost control signals F<1:Y> may pulse within the first voltage range, the inventive concept is not limited to this, and the first to Y^{th} boost control signals F<1:Y> may be generated to pulse within a second voltage range different from the first voltage range. However it is desirable that the second voltage range may be set upon consideration of an operational voltage range of a circuit (not illustrated) coupled to a latter side of the pixel array 220.

The pixel array 220 may include a plurality of pixels PX_11 to PX_XY arranged in a row and a column direction. The pixels PX_11 to PX_XY may generate first to X^{th} pixel signals VPX<1:X> in a row unit based on the first to Y^{th} row control signals ROW CTRLs<1:Y>. For example, the pixels PX_11 to PX_X1 arranged in a first row may simultaneously generate the first to X^{th} pixel signals VPX<1:X> during a first row time based on the first row control signal ROW_CTRL<1>. The pixels PX_1Y to PX_XY arranged in the last row may simultaneously generate the first to X^{th} pixel signals VPX<1:X> during a Y^{th} row time based on the Y^{th} row control signal ROW_CTRL<Y>.

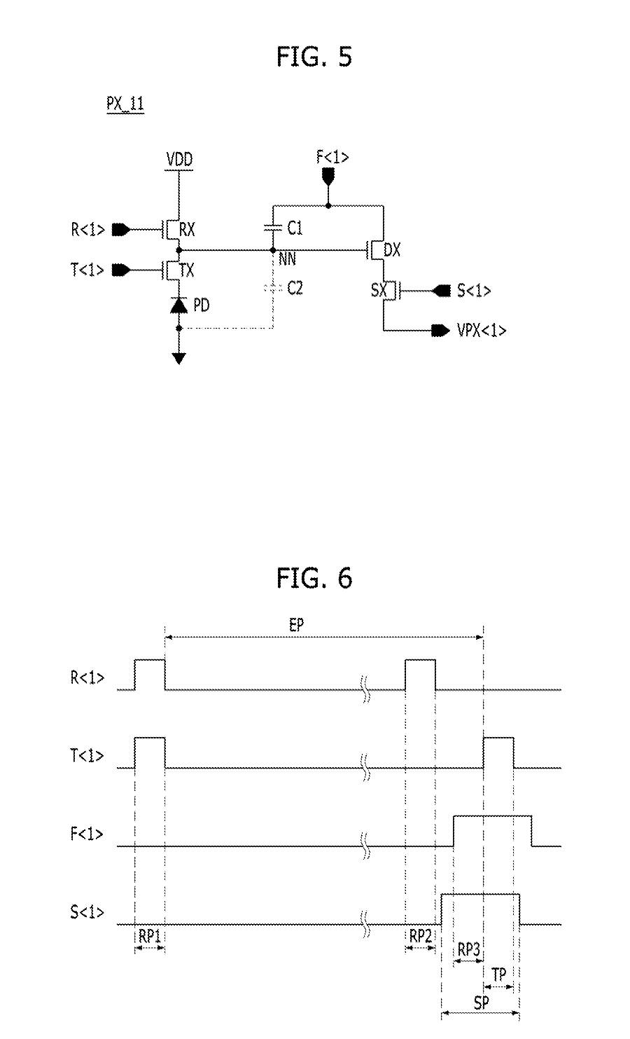

FIG. 5 is a circuit diagram illustrating a pixel among pixels PX_11 to PX_XY according to another embodiment of the present invention. Since the pixels PX_11 to PX_XY have the same structure, the pixel PX_11 arranged at a cross point of the first row and a first column is representatively described hereafter.

Referring to FIG. 5, the pixel PX_11 may include a photodiode PD, a charge transmission node NN, an initialization block RX, a transmission block TX, a first accumulation block C1, and selection blocks DX and SX.

The photodiode PD may generate a photocharge based on incident light during an exposure period EP. The exposure period EP may include a period ranging from a moment when a pixel initialization period RP1 terminates to a moment when a transmission period TP starts.

The initialization block RX may initialize the charge transmission node NN with the power source voltage VDD based on the first initialization control signal R<1>. To be specific, the initialization block RX may drive the charge transmission node NN with the power source voltage VDD during the pixel initialization period RP1 and a data initialization period RP2. Thus, the initialization block RX may precharge the charge transmission node NN at a voltage level corresponding to the power source voltage VDD at the same time of discharging a charge remaining in the first accumulation block C1 to a power source voltage VDD terminal. The data initialization period RP2 may include a portion of period between the pixel initialization period RP1 and a selection period SP. For example, the initialization block RX may include an NMOS transistor having a gate where the first initialization control signal R<1> is inputted and a drain and a source coupled between the power source voltage VDD terminal and the charge transmission node NN.

The transmission block TX may transmit the photocharge to the charge transmission node NN based on the first transmission control signal T<1>. The transmission block TX may transmit the photocharge to the charge transmission node NN during the transmission period TP. The transmission period TP may include a latter period of the selection period SP. The transmission block TX may initialize the photodiode PD based on the first transmission control signal T<1>. The transmission block TX may be enabled along with the initialization block RX during the pixel initialization period RP1 to discharge the photocharge remaining in the photodiode PD to the power source voltage VDD terminal. For example, the transmission block TX may include an NMOS transistor having a gate where the first transmission control signal T<1> is inputted and a drain and a source coupled between the charge transmission node NN and the photodiode PD.

The first accumulation block C1 may boost the charge transmission node NN with the power source voltage VDD during a boosting period based on the first boost control signal F<1>. For example, the first accumulation block C1 may include a parallel-plate capacitor and may boost the charge transmission node NN with the power source voltage VDD corresponding to the first boost control signal F<1> based on a capacitive coupling effect. The boosting period may include a reference period RP3 and the transmission period TP. The reference period RP3 may include an initial period of the selection period SP. The first accumulation block C1 may accumulate the photocharge transmitted to the charge transmission node NN during the transmission period TP.

The selection blocks DX and SX may generate the first pixel signal VPX<1> corresponding to a voltage loaded on the charge transmission node NN based on the first selection control signal S<1>. The selection blocks DX and SX may generate a reference signal corresponding to a double power source voltage VDD+VDD as the first pixel signal VPX<1> during the reference period RP3 and generate a data signal corresponding to the photocharge as the first pixel signal VPX<1> during the transmission period TP. For example, the selection blocks DX and SX may include a driving unit DX and an output unit SX. The driving unit DX may drive the first pixel signal VPX<1> with the power source voltage VDD corresponding to the first boost control signal F<1> based on the voltage loaded on the charge transmission node NN. For example, the driving unit DX may include an NMOS transistor having a gate coupled to the charge transmission node NN and a drain and a source coupled between an input terminal of the first boost control signal F<1> and the output unit SX. The output unit SX may output the first pixel signal VPX<1> based on the first selection control signal S<1>. For example, the output unit SX may include an NMOS transistor having a gate where the first selection control signal S<1> is inputted and a drain and a source coupled between the driving unit DX and an output terminal of the first pixel signal VPX<1>.

The pixel PX_11 may further include a second accumulation block C2. The second accumulation block C2 may be formed between the charge transmission node NN and a ground voltage GND terminal. The second accumulation block C2 may accumulate the photocharge transmitted to the charge transmission node NN during the transmission period TP together with the first accumulation block C1. For example, the second accumulation block C2 may include a junction capacitor.

The pixel PX_11 having the aforementioned structure may sequentially generate the reference signal and the data signal as the first pixel signal VPX<1> when the charge transmission node NN is precharged with the power source voltage VDD and boosted with the power source voltage VDD based on the capacitive coupling effect, based on the first row control signal ROW_CTRL<1>.

Hereinafter, an operation of the image sensing device 200 having the aforementioned structure is described. As an example an operation corresponding to the pixel PX_11 arranged at a cross point of the first row and the first column is described below,

FIG. 6 is a timing diagram for describing the operation of the pixel PX_11 included in the image sensing device 200, according to another embodiment of the present invention.

Referring to FIG. 6, the row controller 210 may generate the first row control signal ROW_CTRL<1> during the first row time. For example, the first control block 210_1 may enable the first initialization control signal R<1> and the first transmission control signal T<1> during the pixel initialization period RP1. The first control block 210_1 may also enable the first initialization control signal R<1> during the data initialization period RP2 after the pixel initialization period RP1 and enable the first selection control signal S<1> during the selection period SP. In addition, the first control block 210_1 may enable the first boost control signal F<1> during the reference period RP3 and the transmission period TP and enable the first transmission control signal T<1> during the transmission period TP. The reference period RP3 may include the initial period of the selection period SP, and the transmission period TP may include the latter period of the selection period SP.

The pixel PX_11 may generate the first pixel signal VPX<1> based on the first row control signal ROW_CTRL<1>. Detailed descriptions thereon are as follows.

The pixel PX_11 may initialize the photodiode PD and the charge transmission node NN with the power source voltage VDD during the pixel initialization period RP1 based on the first initialization control signal R<1> and the first transmission control signal T<1>. For example, the initialization block RX may discharge the charge remaining in the first accumulation block C1 to the power source voltage VDD terminal during the pixel initialization period RP1 based on the first initialization control signal R<1>, and at the same time, the transmission block TX may discharge the charge remaining in the photodiode PD to the power source voltage VDD terminal through a medium of the initialization block RX during the pixel initialization period RP1 based on the first transmission control signal T<1>.

The pixel PX_11 may initialize the charge transmission node NN with the power source voltage VDD during the pixel initialization period RP1 based on the first initialization control signal R<1>. For example, the initialization block RX may precharge the charge transmission node NN with the power source voltage VDD during the data initialization period RP2 based on the first initialization control signal R<1>.

The pixel PX_11 may generate the reference signal corresponding to the double power source voltage VDD+VDD as the first pixel signal VPX<1> during the reference period RP3 and subsequently generate the data signal corresponding to the photocharge as the first pixel signal VPX<1> during the transmission period TP, based on the first selection control signal S<1>, the first boost control signal F<1> and the first transmission control signal T<1>. For example, the first accumulation block C1 may boost the charge transmission node NN with the power source voltage VDD during the reference period RP3 and the transmission period TP based on the first boost control signal F<1>. For example, the first accumulation block C1 may boost the charge transmission node NN with the power source voltage VDD corresponding to the first boost control signal F<1> based on the capacitive coupling effect. The charge transmission node NN may have a combined voltage level VDD+VDD of the power source voltage VDD and the power source voltage VDD. The transmission block TX may transmit the photocharge generated from the photodiode PD to the charge transmission node NN during the transmission period TP based on the first transmission control signal T<1>. The selection blocks DX and SX may generate the reference signal corresponding to the double power source voltage VDD+VDD as the first pixel signal VPX<1> during the reference period RP3 and generate the data signal corresponding to the photocharge as the first pixel signal VPX<1> during the transmission period TP, based on the voltage loaded on the charge transmission node NN. The selection blocks DX and SX may generate the first pixel signal VPX<1> based on the power source voltage VDD corresponding to the first boost control signal F<1>.

The photodiode PD may generate the photocharge during the exposure period EP between a moment when the pixel initialization period RP1 terminates and a moment when the transmission period TP starts.

In accordance with the embodiments of the present invention, as the charge transmission node NN is boosted with a voltage level VDD+V_fd or VDD+VDD which is higher than the power source voltage VDD, a drain-source voltage Vds of the NMOS transistor to included in the transmission block TX may increase, and the transmission capability of the transmission block TX may be improved during the transmission period TP.

Consequently, in accordance with the embodiments of the present invention, as the transmission capability to transmit the photocharge generated from the photodiode to the charge transmission node is improved charge losses and image lag may decrease.

While the present invention has been described with respect to specific embodiments the embodiments are not intended to be restrictive, but rather descriptive. Further, it is noted that the present invention may be achieved in various ways through substitution, change, and modification, by those skilled in the art without departing from the spirit and/or scope of the present invention as defined by the following claims.

What is claimed is:

1. A pixel, comprising:
a charge transmission node;
an initialization block suitable for initializing the charge transmission node with a first voltage during a data initialization period;
a photodiode suitable for generating a photocharge based on incident light during an exposure period;
a transmission block suitable for transmitting the photocharge to the charge transmission node during a transmission period;
a first accumulation block suitable for boosting the charge transmission node with a second voltage during a boosting period and accumulating the photocharge transmitted to the charge transmission node during the transmission period; and
a selection block suitable for generating a pixel signal corresponding to a voltage loaded n the charge transmission node during a selection period.

2. The pixel of claim 1, wherein the first accumulation block includes a parallel-plate capacitor.

3. The pixel of claim 1, wherein the first voltage and the second voltage have the same voltage level or different voltage levels.

4. The pixel of claim wherein the selection block includes:
a driving unit suitable for driving the pixel signal with the first voltage; and
an output unit suitable for outputting the pixel signal during the selection period.

5. The pixel of claim wherein the selection block includes:
a driving unit suitable for driving the pixel signal with the second voltage; and
an output unit suitable for outputting the pixel signal during the selection period.

6. The pixel of claim 1, further comprising:
a second accumulation block formed between the charge transmission node and a ground voltage terminal and suitable for accumulating the photocharge transmitted to the charge transmission node during the transmission period.

7. The pixel of claim 6, wherein the second accumulation block includes a junction capacitor.

8. The pixel of claim 1, wherein the initialization block initializes the first accumulation block with the first voltage during a pixel initialization period, and
the transmission block initializes the photodiode with the first voltage during the pixel initialization period.

9. An image sensing device, comprising:
a control block suitable for generating an initialization control signal, a transmission control signal and a selection control signal that pulse within a first voltage range and generating a boost control signal that pulses within a second voltage range; and
a pixel suitable for initializing a charge transmission node before a transmission period, boosting the charge transmission node based on a capacitive coupling effect during the transmission period, transmitting a photocharge generated from a photodiode to the charge transmission node during the transmission period, and generating a pixel signal corresponding to a voltage loaded on the charge transmission node during the transmission period, based on the initialization control signal the transmission control signal the selection control signal and the boost control signal.

10. The image sensing device of claim 9, wherein the pixel includes:
a charge transmission node;
an initialization block suitable for initializing the charge transmission node with a first voltage based on the initialization control signal;
the photodiode suitable for generating the photocharge based on incident light during an exposure period;
a transmission block suitable for transmitting the photocharge to the charge transmission node based on the transmission control signal;
a first accumulation block suitable for boosting the charge transmission node with a second voltage corresponding to the boost control signal and accumulating the photocharge transmitted to the charge transmission node; and
a selection block suitable for generating the pixel signal corresponding to the voltage loaded on the charge transmission node based on the selection control signal.

11. The image sensing device of claim 10, wherein the first accumulation block includes a parallel-plate capacitor.

12. The image sensing device of claim 10, wherein the first voltage and the second voltage have the same voltage level or different voltage levels.

13. The image sensing device of claim 12, wherein the selection block includes:
a driving unit suitable for driving he pixel signal with the first voltage; and
an output unit suitable for outputting the pixel signal,

14. The image sensing device of claim 12, wherein the selection block includes:
a driving unit suitable for driving the pixel signal with the second voltage; and
an output unit suitable for outputting the pixel signal.

15. The image sensing device of claim 10, wherein the pixel further includes:
a second accumulation block formed between the charge transmission node and a ground voltage terminal and suitable for accumulating the photocharge transmitted to the charge transmission node during the transmission period.

16. The image sensing device of claim 15 wherein the second accumulation block includes a junction capacitor.

17. The image sensing device of claim 10, wherein the initialization block initializes the first accumulation block with the first voltage during a pixel initialization period before the exposure period based on the initialization control signal, and
the transmission block initializes the photodiode with the first voltage during the pixel initialization period based on the transmission control signal.

18. A method for driving an image sensing device, comprising:
initializing a charge transmission node with a first voltage; and
transmitting a photocharge generated from a photodiode to the charge transmission node and generating a pixel signal based on a voltage loaded on the charge transmission node when the charge transmission node is boosted with a second voltage based on a capacitive coupling effect.

19. The method of claim 18, wherein the initializing of the charge transmission node with the first voltage is carried out during a data initialization period before a selection period, and
the generating of the pixel signal includes boosting the charge transmission node during the selection period, generating a reference signal corresponding to the first and second voltages as the pixel signal during a reference period of the selection period, and transmitting the photocharge to the charge transmission node and generating a data signal corresponding to the photocharge as the pixel signal during a transmission period of the selection period.

20. The method of claim 18, further comprising:
initializing the transmission node and the photodiode with the first voltage before the initializing of the charge transmission node with the first voltage.
